(19) United States
(12) Patent Application Publication
(10) Pub. No.: US 2026/0184054 A1
(43) Pub. Date: Jul. 2, 2026

(54) MASS TRANSFER FILM AND METHOD FOR MANUFACTURING THE SAME

(71) Applicant: San Fang Chemical Industry Co., Ltd., Kaohsiung City (TW)

(72) Inventors: CHIH-YI LIN, Kaohsiung City (TW); Kuo-Kuang CHENG, Kaohsiung City (TW); Chi-Chin CHIANG, Kaohsiung City (TW); Wen-Hsin TAI, Kaohsiung City (TW); Qing-Hao YANG, Kaohsiung City (TW); Chun-Chieh HUANG, Kaohsiung City (TW)

(21) Appl. No.: 19/410,798

(22) Filed: Dec. 5, 2025

(30) Foreign Application Priority Data
Dec. 27, 2024 (TW) 113151174

(51) Int. Cl. B32B 27/40; B32B 27/08; B32B 27/18; B32B 27/30; B32B 27/32; B32B 37/12; B32B 37/15

(52) U.S. Cl. CPC B32B 27/40; B32B 27/08; B32B 27/18; B32B 27/306; B32B 27/32; B32B 37/1284; B32B 37/153; B32B 2250/03; B32B 2274/00; B32B 2307/536; B32B 2307/54; B32B 2331/04; B32B 2375/00

(57) ABSTRACT

A mass transfer film and a method for manufacturing the mass transfer film are provided. The mass transfer film includes a base material layer and an adhesive layer. The base material layer includes a support layer and a buffer layer. The buffer layer is arranged on the support layer. The adhesive layer is arranged on the buffer layer of the base material layer. Compared with the prior art, the mass transfer film provided in the present invention may prevent dies from excessively sinking into the adhesive layer, facilitate peeling of the dies, avoid occurrence of die breakage, and prevent adhesive residue from remaining after the dies are peeled off.

### BACKGROUND

### 1. Field of the Disclosure

The present invention relates to the field of mass transfer technologies, particularly to a mass transfer film and a method for manufacturing the mass transfer film.

### 2. Description of the Related Art

The mass transfer technology is one of the key technologies in the manufacturing process of Micro/Mini light-emitting diode (Micro/Mini LED) displays, which has a decisive impact on the process yield and output of the Micro/Mini LED displays. In the existing mass transfer process, a mass transfer film is used as a temporary carrier to hold a Micro/Mini LED, facilitating execution of subsequent die transfer processes. However, during bonding of the Micro/Mini LED with the existing mass transfer film, the Micro/Mini LED often sinks into the adhesive layer of the mass transfer film. This leads to problems such as a failure of the Micro/Mini LED to peel off from the mass transfer film, die breakage after separation, or adhesive residue remaining on the LED.

Therefore, it is necessary to improve the mass transfer film in the prior art to resolve the foregoing existing problems.

### SUMMARY

In some embodiments of the present application, a mass transfer film includes a base material layer and an adhesive layer. The base material layer includes a support layer and a buffer layer. The buffer layer is arranged on the support layer. The adhesive layer is arranged on the buffer layer of the base material layer.

In some embodiments of the present application, a method for manufacturing a mass transfer film includes: co-extruding a support layer and a buffer layer to form a base material layer; and forming an adhesive layer on the buffer layer of the base material layer.

Compared with the prior art, the mass transfer film of the present invention has at least the following technical effects, which may prevent dies from excessively sinking into the adhesive layer, facilitate peeling of the dies, avoid occurrence of die breakage, and prevent adhesive residue from remaining after the dies are peeled off.

### BRIEF DESCRIPTION OF THE DRAWINGS

Implementations of some embodiments of the utility model are readily understood from the following detailed description when read with reference to the accompanying drawings. It should be noted that various structures may not be drawn to scale, and dimensions of the various structures may be arbitrarily increased or reduced for clarity of discussion.

FIG. 1 illustrates a schematic diagram of a cross-section of a mass transfer film according to some embodiments of the present application.

FIG. 2 illustrates a schematic diagram of one or more stages according to some embodiments of a method for manufacturing a mass transfer film of the present application.

### DETAILED DESCRIPTION

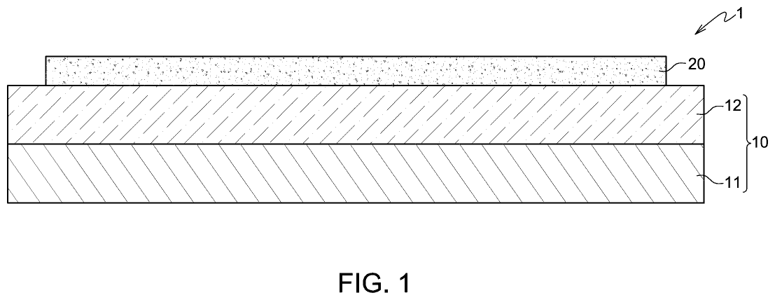

Refer to FIG. 1, which illustrates a schematic diagram of a cross-section of a mass transfer film 1 according to some embodiments of the present application. The mass transfer film 1 of the present invention includes a base material layer 10 and an adhesive layer 20.

In some embodiments of the present application, as shown in FIG. 1, the base material layer 10 may include a support layer 11 and a buffer layer 12. In some embodiments of the present application, the material of the support layer 11 may include thermoplastic polyolefin (TPO) (for example, including polypropylene (PP)), an ethylene-vinyl acetate copolymer (EVA), thermoplastic polyurethane (TPU), or a composition of at least two thereof. In some embodiments of the present application, the support layer 11 may further include an antistatic agent, a heat stabilizer, an antioxidant, an ultraviolet absorber, a lubricating agent, or an anti-adhesion agent. In some embodiments of the present application, the thickness of the support layer 11 may account for 50% to 70% of the total thickness of the base material layer 10. In some embodiments of the present application, the Shore hardness of the support layer 11 may range from 60 A to 70 D. In some embodiments of the present application, the melt index of the support layer 11 may be range from 10.0 g/10 min to 25.0 g/10 min, and the melting point of the support layer 11 may be greater than 130° C.

The buffer layer 12 may be arranged on the support layer 11. In some embodiments of the present application, the material of the buffer layer 12 may include thermoplastic polyolefin (TPO) (for example, including polypropylene (PP)), an ethylene-vinyl acetate copolymer (EVA), thermoplastic polyurethane (TPU), or a composition of at least two thereof. In some embodiments of the present application, the buffer layer 12 may further include an antistatic agent, a heat stabilizer, an antioxidant, an ultraviolet absorber, a lubricating agent, or an anti-adhesion agent. In some embodiments of the present application, the thickness of the buffer layer 12 may be less than or equal to the thickness of the support layer 11. In some embodiments of the present application, the thickness of the buffer layer 12 may account for 30% to 50% of the total thickness of the base material layer 10. In some embodiments of the present application, the Shore hardness of the buffer layer 12 may be less than the Shore hardness of the support layer 11. In some embodiments of the present application, the melt index of the buffer layer 12 may be range from 10.0 g/10 min to 25.0 g/10 min, and the melting point of the buffer layer 12 may be greater than 130° C.

In some embodiments of the present application, the total thickness of the base material layer 10 (including the support layer 11 and the buffer layer 12) may range from 50 μm to 150 μm (for example, including 60 μm to 140 μm, 70 μm to 130 μm, 80 μm to 120 μm, or 90 μm to 110 μm). Through the setting of this thickness range, the transfer performance of the mass transfer film 1 may be improved. In some embodiments of the present application, the tensile strength of the base material layer 10 (including the support layer 11 and the buffer layer 12) may range from 80 MPa to 120 MPa. In addition, in some embodiments of the present application, a ratio of the tensile strength of the base material layer 10 (including the support layer 11 and the buffer layer 12) in a machine direction to the tensile strength of the base material layer in a transverse direction may range from 0.95 to 1.05. In some embodiments of the present application, the machine direction may include a calendering direction of the base material layer 10, and the transverse direction may include a direction perpendicular to the calendering direction.

The adhesive layer 20 is arranged on the buffer layer 12 of the base material layer 10. In some embodiments of the present application, the adhesive layer 20 may be an adhesive resin material. In some embodiments of the present application, the thickness of the adhesive layer 20 may be less than the thickness of the buffer layer 12, to reduce the sinking depth of a die (for example, a Micro/Mini LED) into the adhesive layer 20. In some embodiments of the present application, the thickness of the adhesive layer 20 may range from 4 μm to 20 μm (for example, including 4 μm to 16 μm, 4 μm to 12 μm, or 4 μm to 8 μm). In some embodiments of the present application, surface tension of the buffer layer 12 may be greater than or equal to 33 dynes per centimeter (dyne/cm) to increase adhesion between the adhesive layer 20 and the buffer layer 12.

In the present invention, the support layer 11 is arranged to provide sufficient support for dies, to prevent the excessive sinking of the dies into the adhesive layer 20, thereby facilitating easy peeling of the dies. The buffer layer 12 is arranged, so that stress concentration on the dies may be reduced during peeling of the dies, thereby avoiding occurrence of die breakage. The adhesion between the adhesive layer 20 and the buffer layer 12 is increased, so that adhesive residue can be prevented from remaining after the dies are peeled off. Therefore, compared with the prior art, the mass transfer film 1 of the present invention has at least the following technical effects, which may (1) prevent dies from excessively sinking into the adhesive layer 20; (2) facilitate peeling of the dies; (3) avoid occurrence of die breakage; and (4) prevent adhesive residue from remaining after the dies are peeled off.

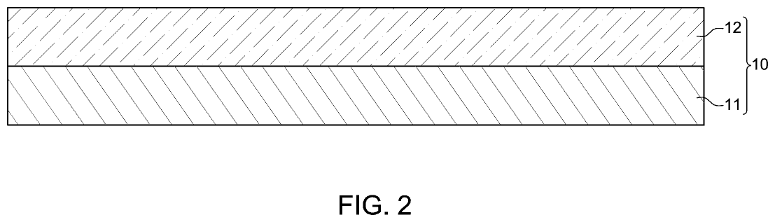

FIG. 2 illustrates a schematic diagram of one or more stages according to some embodiments of a manufacturing method for a mass transfer film of the present application.

Referring to FIG. 2, a support layer 11 and a buffer layer 12 are co-extruded to form a base material layer 10. The support layer 11 in FIG. 2 may be the same as the support layer 11 in FIG. 1. The buffer layer 12 in FIG. 2 may be the same as the buffer layer 12 in FIG. 1. Therefore, the base material layer 10 in FIG. 2 may be substantially the same as the base material layer 10 in FIG. 1.

Surface treatment is performed on the buffer layer 12 of the base material layer 10, so that surface tension of the buffer layer 12 is greater than or equal to 33 dynes per centimeter. In some embodiments of the present application, a method for the surface treatment may include corona treatment, plasma treatment, hot air treatment, ozone treatment, or ultraviolet treatment.

Referring to FIG. 1, the adhesive layer 20 is formed on the buffer layer 12 of the base material layer 10. In some embodiments of the present application, the adhesive layer 20 may be formed by uniformly coating solvent-containing resinous adhesive onto the buffer layer 12 through a coater. In some embodiments of the present application, the coater may include a roll coater, a blade coater, a roll-blade coater, an air knife coater, a slot die coater, a bar coater, a gravure coater, or a curtain coater.

After a drying step, the mass transfer film 1 as shown in FIG. 1 may be obtained.

The present invention is described in detail through the following examples, but this does not mean that the present invention is limited only to the content disclosed in these examples.

### Embodiment 1

The material of a layer A (support layer) is polypropylene (PP) with the Shore hardness of 70 D.

The material of a layer B (buffer layer) is polypropylene (PP) with the Shore hardness of 64 A.

Temperature of an extruder die: 180° C. to 200° C.

A thickness ratio (A):(B) is 50 μm:50 μm.

Thickness of an adhesive layer: 5 μm.

Drying condition for the adhesive layer: Heat at 110° C. for 3 minutes.

Based on the foregoing process condition and the manufacturing method of the present invention, the fabrication of the base material layer and the mass transfer film of Embodiment 1 is completed.

### Embodiment 2

The material of a layer A (support layer) is polypropylene (PP) with the Shore hardness of 70 D.

The material of a layer B (buffer layer) is an ethylene-vinyl acetate copolymer (EVA) with the Shore hardness of 22 D.

Temperature of an extruder die: 180° C. to 200° C.

A thickness ratio (A):(B) is 50 μm:50 μm.

Thickness of an adhesive layer: 5 μm.

Drying condition for the adhesive layer: Heat at 110° C. for 3 minutes.

Based on the foregoing process condition and the manufacturing method of the present invention, the fabrication of the base material layer and the mass transfer film of Embodiment 2 is completed.

### Embodiment 3

The material of a layer A (support layer) is polypropylene (PP) with the Shore hardness of 70 D.

The material of a layer B (buffer layer) is thermoplastic polyurethane (TPU) with the Shore hardness of 90 A.

Temperature of an extruder die: 180° C. to 200° C.

A thickness ratio (A):(B) is 50 μm:50 μm.

Thickness of an adhesive layer: 5 μm.

Drying condition for the adhesive layer: Heat at 110° C. for 3 minutes.

Based on the foregoing process condition and the manufacturing method of the present invention, the fabrication of the base material layer and the mass transfer film of Embodiment 3 is completed.

### Embodiment 4

The material of a layer A (support layer) is polypropylene (PP) with the Shore hardness of 70 D.

The material of a layer B (buffer layer) is thermoplastic polyurethane (TPU) with the Shore hardness of 70 A.

Temperature of an extruder die: 180° C. to 200° C.

A thickness ratio (A):(B) is 50 μm:50 μm.

Thickness of an adhesive layer: 5 μm.

Drying condition for the adhesive layer: Heat at 110° C. for 3 minutes.

Based on the foregoing process condition and the manufacturing method of the present invention, the fabrication of the base material layer and the mass transfer film of Embodiment 4 is completed.

### Comparative Example 1

The material of a layer A (support layer) is polypropylene (PP) with the Shore hardness of 70 D.

No layer B (buffer layer) is arranged.

A thickness ratio (A):(B) is 90 μm:0 μm.

Thickness of an adhesive layer: 15 μm.

Drying condition for the adhesive layer: Heat at 110° C. for 3 minutes.

Based on the foregoing process condition, the fabrication of the base material layer and the mass transfer film of Comparative Example 1 is completed.

### Comparative Example 2

No layer A (support layer) is arranged.

The material of a layer B (buffer layer) is thermoplastic polyurethane (TPU) with the Shore hardness of 70 A.

A thickness ratio (A):(B) is 0 μm:100 μm.

Thickness of an adhesive layer: 5 μm.

Drying condition for the adhesive layer: Heat at 110° C. for 3 minutes.

Based on the foregoing process condition, the fabrication of the base material layer and the mass transfer film of Comparative Example 2 is completed.

### <Feature Evaluation Manner>

### (1) Tensile Strength

A specimen of the base material layer has a size of 150 mm×10 mm. Under the conditions of a gauge distance of 75 mm and a crosshead speed of 300 mm/min, a tensile testing machine at a testing temperature of 25° C. is used to perform a tensile test on the foregoing specimen of the base material layer, to determine the tensile strength at break of the specimen. To maintain good transfer accuracy of a Micro/Mini LED, the mass transfer film will not undergo film deformation or sagging due to tension during transfer. The evaluation manner of the tensile strength is as follows:

The tensile strength of the base material layer that ranges from 100 MPa to 120 MPa is rated as ⊚, the tensile strength of the base material layer that ranges from 80 MPa to 100 MPa is rated as ◯, and the tensile strength of the base material layer that is less than 80 MPa is rated as X.

### (2) Light Transmittance

The specimen of the base material layer has a size of 50 mm×50 mm. A color difference spectrophotometer is used to determine the light transmittance of the specimen at a wavelength of 355 nm. The evaluation manner of the light transmittance is as follows:

The light transmittance of the base material layer at the wavelength of 355 nm that is greater than 90% is rated as, and the light transmittance of the base material layer at the wavelength of 355 nm that is less than 90% is rated as

### (3) Temperature Resistance

The specimen of the mass transfer film has a size of 100 mm×10 mm, which is placed in an oven and baked at 130° C. for 60 minutes, then taken out and placed at room temperature for cooling, and irradiated with UV light after being cooled. After the UV light irradiation, a 180° peel force is tested through a universal tensile testing machine. The evaluation manner of the temperature resistance is as follows:

The peel force of the base material layer after the UV light irradiation that is less than 50 gf/in is rated as PASS, and the peel force of the base material layer after the UV light irradiation that is greater than 50 gf/in is rated as NG.

### (4) Adhesive Residue Condition Test

The specimen of the mass transfer film has a size of 25 mm×25 mm. First, a substrate with Micro/Mini LED dies thereon is prepared, and then an adhesive layer is attached to the substrate at room temperature and rolled with a rolling roller weighing 2 KG, then irradiated with UV light, and then peeled at 180°. Finally, the adhesive residue condition is examined through an electron microscope.

The process conditions and feature evaluation results of Embodiments 1-4 and Comparative Examples 1-2 are summarized in Table 1 below.

TABLE 1

| | | Embodiment | Embodiment | Embodiment | Embodiment | Comparative | Comparative |
|---|---|---|---|---|---|---|---|
| | | 1 | 2 | 3 | 4 | Example 1 | Example 2 |
| Base | Support Layer | PP (70D) | PP (70D) | PP (70D) | PP (70D) | PP (70D) | — |
| material | (A) | | | | | | |
| layer | Buffer layer | PP (64A) | EVA (22D) | TPU (90A) | TPU (70A) | — | TPU (70A) |
| | (B) | | | | | | |
| | Thickness | 50 μm:50 | 50 μm:50 | 50 μm:50 | 50 μm:50 | 90 μm:0 | 0 μm:100 |
| | ratio | μm | μm | μm | μm | μm | μm |
| | (A):(B) | | | | | | |
| | Tensile | ◯ | ◯ | ⊚ | ◯ | ⊚ | X |
| | strength | | | | | | |
| Mass | Light | ◯ | ◯ | ◯ | ◯ | ◯ | ◯ |
| transfer | transmittance | | | | | | |
| film | Adhesive layer | 5 μm | 5 μm | 5 μm | 5 μm | 15 μm | 5 μm |
| | Thickness | | | | | | |
| | Temperature | PASS | PASS | PASS | PASS | NG | PASS |
| | resistance | | | | | | |
| | Adhesive | No adhesive | No adhesive | No adhesive | No adhesive | With adhesive | With adhesive |
| | residue | residue | residue | residue | residue | residue | residue |
| | condition | | | | | | |

The foregoing embodiments describe only the principle and efficacy of the present invention, and are not intended to limit the present invention. Modifications and variations made to the foregoing embodiments by a person skilled in the art do not depart from the spirit of the present invention. The scope of rights of the present invention shall be as set forth in the claims described below.

What is claimed is:

1. A mass transfer film, comprising:
a base material layer, comprising:
a support layer; and
a buffer layer, arranged on the support layer; and
an adhesive layer, arranged on the buffer layer of the base material layer.

2. The mass transfer film of claim 1, wherein the material of the support layer comprises thermoplastic polyolefin, an ethylene-vinyl acetate copolymer, thermoplastic polyurethane, or a composition of at least two thereof.

3. The mass transfer film of claim 1, wherein the material of the buffer layer comprises thermoplastic polyolefin, an ethylene-vinyl acetate copolymer, thermoplastic polyurethane, or a composition of at least two thereof.

4. The mass transfer film of claim 1, wherein the support layer and the buffer layer comprise an antistatic agent, a heat stabilizer, an antioxidant, an ultraviolet absorber, a lubricating agent, or an anti-adhesion agent.

5. The mass transfer film of claim 1, wherein the thickness of the buffer layer is less than or equal to the thickness of the support layer, and the thickness of the adhesive layer is less than the thickness of the buffer layer.

6. The mass transfer film of claim 5, wherein the thickness of the support layer accounts for 50% to 70% of the total thickness of the base material layer, and the thickness of the buffer layer accounts for 30% to 50% of the total thickness of the base material layer.

7. The mass transfer film of claim 1, wherein the melt index of the support layer ranges from 10.0 g/10 min to 25.0 g/10 min, the melting point of the support layer is greater than 130° C., the melt index of the buffer layer ranges from 10.0 g/10 min to 25.0 g/10 min, and the melting point of the buffer layer is greater than 130° C.

8. The mass transfer film of claim 1, wherein the Shore hardness of the buffer layer is less than the Shore hardness of the support layer, the Shore hardness of the support layer ranges from 60 A to 70 D, the tensile strength of the base material layer ranges from 80 MPa to 120 MPa, and a ratio of the tensile strength of the base material layer in a machine direction to the tensile strength of the base material layer in a transverse direction ranges from of 0.95 to 1.05.

9. The mass transfer film of claim 1, wherein the surface tension of the buffer layer is greater than or equal to 33 dynes per centimeter (dyne/cm).

10. A method for manufacturing a mass transfer film, comprising:
co-extruding a support layer and a buffer layer to form a base material layer; and
forming an adhesive layer on the buffer layer of the base material layer.
